(19) United States
(12) Patent Application Publication
(10) Pub. No.: US 2011/0244677 A1
(43) Pub. Date: Oct. 6, 2011

(54) METHOD OF MANUFACTURING SEMICONDUCTOR DEVICE AND SEMICONDUCTOR DEVICE MANUFACTURING APPARATUS

(75) Inventor: Tamotsu Owada, Yokohama (JP)

(73) Assignee: FUJITSU SEMICONDUCTOR LIMITED, Yokohama-shi (JP)

(21) Appl. No.: 13/073,282

(22) Filed: Mar. 28, 2011

(30) Foreign Application Priority Data
Mar. 31, 2010 (JP) 2010-082098

(51) Int. Cl. H01L 21/768; H01L 21/683

(52) U.S. Cl. 438/653; 250/453.11; 257/E21.584

(57) ABSTRACT

A method of manufacturing a semiconductor device includes: forming a first conductive film on a substrate; forming an insulating film to cover the conductive film; etching the insulating film to form an opening portion to expose at least a portion of the first conductive film in the insulating film; irradiating the opening portion with ultraviolet rays in a reduction gas atmosphere; forming a barrier metal film in the opening portion; and forming a second conductive film on the barrier metal film.

### CROSS-REFERENCE TO RELATED APPLICATIONS

This application claims the benefit of priority from Japanese Patent Application No. 2010-82098 filed on Mar. 31, 2010, the entire contents of which are incorporated herein by reference.

### BACKGROUND

1. Field

Embodiments discussed herein relate to a method of manufacturing a semiconductor device and a semiconductor device manufacturing apparatus.

2. Description of Related Art

The transmission rate of signals in multilayer wiring of a semiconductor device is influenced by wiring resistance and parasitic capacitance between wirings.

Relating art is disclosed in Japanese Laid-open Patent Publication No. 2009-32708, Japanese Laid-open Patent Publication No. 2000-68274, Japanese Laid-open Patent Publication No. 2000-174019, Japanese Laid-open Patent Publication No. 2004-193453, Non-patent Document “Removal of Plasma-Modified Low-k Layer Using Dilute HF: Influence of Concentration (Electrochemical and Solid-State Letters, 8(7) F21-F24 (2005)”, etc.

### SUMMARY

According to one aspect of the embodiments, a method of manufacturing a semiconductor device includes: forming a first conductive film on a substrate; forming an insulating film to cover the conductive film; etching the insulating film to form an opening portion to expose at least a portion of the first conductive film in the insulating film; irradiating the opening portion with ultraviolet rays in a reduction gas atmosphere; forming a barrier metal film in the opening portion; and forming a second conductive film on the barrier metal film.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 illustrates an exemplary measurement sample.

FIG. 2 illustrates an exemplary dielectric constant of a low dielectric constant film.

FIG. 3 illustrates exemplary I-V characteristics.

FIG. 4 illustrates an exemplary refractive index of a low dielectric constant film.

FIG. 5 illustrates an exemplary degassing analysis.

FIG. 6 illustrates an exemplary dielectric constant of a low dielectric constant film.

FIG. 7 illustrates an exemplary dielectric constant of a low dielectric constant film.

FIG. 8 illustrates an exemplary semiconductor device manufacturing apparatus.

FIGS. 9A to 9S illustrate an exemplary method for manufacturing a semiconductor device.

### DESCRIPTION OF EMBODIMENTS

A material having a lower dielectric constant than that of SiO₂ (low dielectric constant material) is used as an insulating interlayer, and a semiconductor device with a reduced wiring capacity is provided. For example, the dielectric constant of SiO₂ may be about 4.0 to about 4.5.

Examples of the low dielectric constant film include an organic polyarylene film and an organic polyaryl ether film which are formed by a spin-on process, an inorganic hydrogen silsesquioxane (HSQ) film and an inorganic methyl silsesquioxane (MSQ) film, a film including a mixed material of HSQ and MSQ, a silicon oxycarbide (SiOC) film formed by a chemical vapor deposition (CVD) method using an organosiloxane material, or a porous silica film whose dielectric constant decreases by holes formed in an insulating material.

The wiring of the low dielectric constant film may be formed in an interlayer insulating film by, for example, a damascene process or the like.

In the damascene process, a wiring groove is formed in the low dielectric constant film, and then a barrier metal film and a Cu film are formed in the wiring groove. During the formation of the wiring groove, the low dielectric constant film may be damaged, the low dielectric constant film may absorb moisture, the barrier metal film may be oxidized, and Cu may be dispersed in the low dielectric constant film. Therefore, the low dielectric constant film may be irradiated with ultraviolet rays in an inactive gas atmosphere after the formation of the wiring groove, and the damages may be recovered.

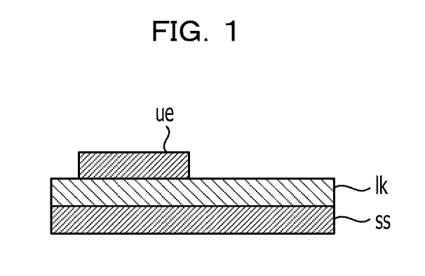

FIG. 1 illustrates an exemplary measurement sample. The measurement sample illustrated in FIG. 1 may be used for measuring the dielectric constant of the low dielectric constant film.

A sample A may be formed by forming a MSQ/HSQ mixed hybrid type porous silica film having a thickness 200 nm by a spin-on process as a low dielectric constant film lk on a low resistance silicon substrate ss in which impurities are doped. After applying NCS® manufactured by Catalysts and Chemicals Industries CO., Ltd. on the entire surface of the low resistance silicon substrate ss, a baking process is carried out at 250° C. for 1 minute, and then a heat process is carried out at 400° C. for 30 minutes in a nitrogen atmosphere in a diffusion furnace.

An Au upper electrode ue is formed on the low dielectric constant film lk. In the formation of the Au upper electrode ue, a metal mask having a circular opening portion is disposed on the surface of the low dielectric constant film lk, and an Au film of 100 nm is formed by vapor deposition. The diameter of the Au upper electrode ue may be 1 mm.

For example, with respect to the sample A, the dielectric constant of the low dielectric constant film lk is calculated to be about 2.3 by capacity measurement using an LCR meter.

For example, a sample B may be formed by forming a low dielectric constant film lk on a low resistance silicon substrate ss under substantially the same formation conditions as those of the sample A. The thickness of the low dielectric constant film lk may be 100 nm. A 50-nm-thick portion of the low dielectric constant film lk is removed by reactive ion etching (RIE) using CF₄ gas. In the etching, the RF power is set to 250 W and the chamber internal pressure is set to 20 Torr. The Au upper electrode ue is formed on the low dielectric constant film lk under substantially the same conditions as those in the formation of the sample A.

With respect to the sample B, the dielectric constant of the low dielectric constant film lk is calculated to be 3.0 by capacity measurement using an LCR meter. The dielectric constant of the low dielectric constant film lk of the sample B is higher than that of the low dielectric constant film lk of the sample A by about 2.3. The etching after forming the low dielectric constant film lk may increase the dielectric constant. The increase in the dielectric constant may cause wiring delay.

A low dielectric constant film lk of 100 nm in thickness is formed on the low resistance silicon substrate ss under substantially the same formation conditions as those of the sample A. A 50-nm-thick portion of the low dielectric constant film lk is removed by etching under substantially the same formation conditions as those of the sample B. The low dielectric constant film lk is irradiated with ultraviolet rays (UV). In the UV irradiation, a high-pressure mercury lamp is used as a light source, a He gas atmosphere is used as the atmosphere, the chamber internal pressure power is set to 10 Torr (under reduced pressure conditions), the UV irradiation intensity is set to 350 mW/cm², the substrate heater temperature is set to 230° C., and the irradiation time is set to 10 minutes. The Au upper electrode ue is formed on the low dielectric constant film lk under the same formation conditions as those of the sample A. The UV from the high-pressure mercury lamp irradiating the low dielectric constant film has a broadband wavelength (150 nm to 400 nm).

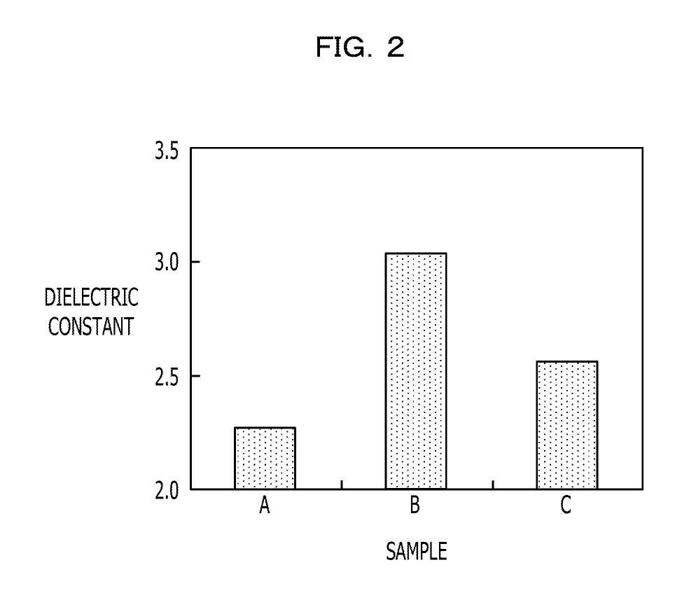

With respect to a sample C, the dielectric constant of a low dielectric constant film lk is calculated to be 2.5 by capacity measurement using an LCR meter. The dielectric constant of the low dielectric constant film lk of the sample C is lower than the dielectric constant of the sample B of 3.0. The dielectric constant decreases by UV irradiation. FIG. 2 illustrates exemplary dielectric constants of low dielectric constant films. The dielectric constants illustrated in FIG. 2 may be those of the low dielectric constant films lk of the samples A, B and C. The vertical axis of FIG. 2 represents the dielectric constant of each sample.

When the dielectric constant of the low dielectric constant film increases by etching, the dielectric constant may decrease by the UV irradiation after the etching.

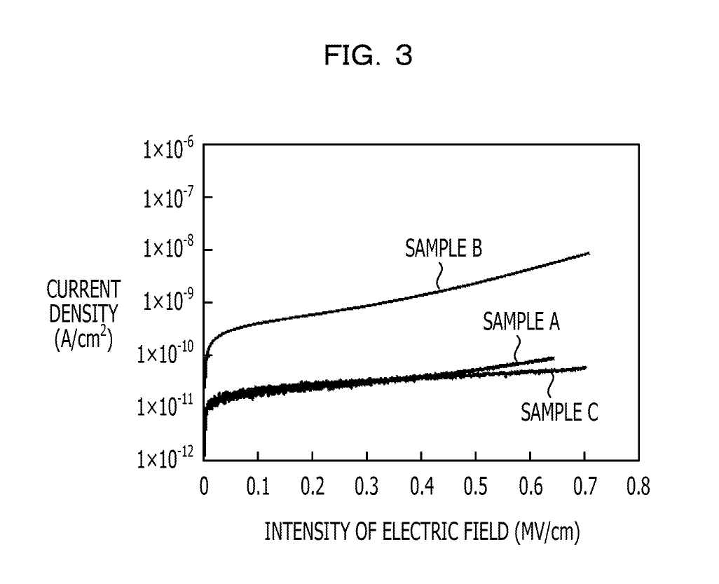

The leakage current characteristics of the samples A, B and C are measured. For each of the samples A, B and C, the change in the current density of the leakage current of the low dielectric constant film lk is measured in relation to the intensity of the electric field to be applied between the low resistance silicon substrate ss and the Au upper electrode ue. FIG. 3 illustrates exemplary I-V characteristics. The I-V characteristics illustrated in FIG. 3 may be those of the samples A, B and C. The horizontal axis of FIG. 3 represents the intensity of the electric field (MV/cm) and the vertical axis represents the current density (A/cm²).

As illustrated in FIG. 3, when the intensity of the electric field is 0.4 (MV/cm) in the sample A, a leakage current of 4.10×10⁻¹⁰ (mA/cm²) flows. In the sample B, when the intensity of the electric field is 0.4 (MV/cm), a leakage current of 1.46×10⁻⁹ (mA/cm²) flows. The leakage current of the sample B is three times the leakage current of the sample A. The leakage current sometimes increases by the damages to the low dielectric constant film lk by etching.

In the sample C, when the intensity of the electric field is 0.4 (MV/cm), a leakage current of 3.85×10⁻¹¹ (mA/cm²) flows. The leakage current of the sample C is lower than the leakage current of the sample A.

Even when the dielectric constant of the low dielectric constant film increases by etching, the leakage current decreases by the UV irradiation after the etching.

When the low dielectric constant film absorbs moisture having a dielectric constant as high as 88, the dielectric constant of the low dielectric constant film increases. Thus, the low dielectric constant material may have water repellency. For example, the surface of the MSQ/HSQ mixed hybrid type porous silica film may be subjected to termination process with hydrophobic Si—H, Si—CH₃, or the like in order to reduce the increase in the dielectric constant of the low dielectric constant film by moisture absorption.

When the low dielectric constant film is etched, the surface of the low dielectric constant film may be damaged. For example, a chemical bond may be destroyed by etching and a hydrophilic Si—OH group may be formed on the surface of the MSQ/HSQ mixed hybrid type porous silica film. The moisture in the air may be absorbed in the surface of the formed hydrophilic Si—OH group film and the dielectric constant of the low dielectric constant film may increase.

When the low dielectric constant film having damage by etching is irradiated with UV, the Si—OH group generated on the surface by etching may be removed and the water absorbency of the surface of the low dielectric constant film may be reduced.

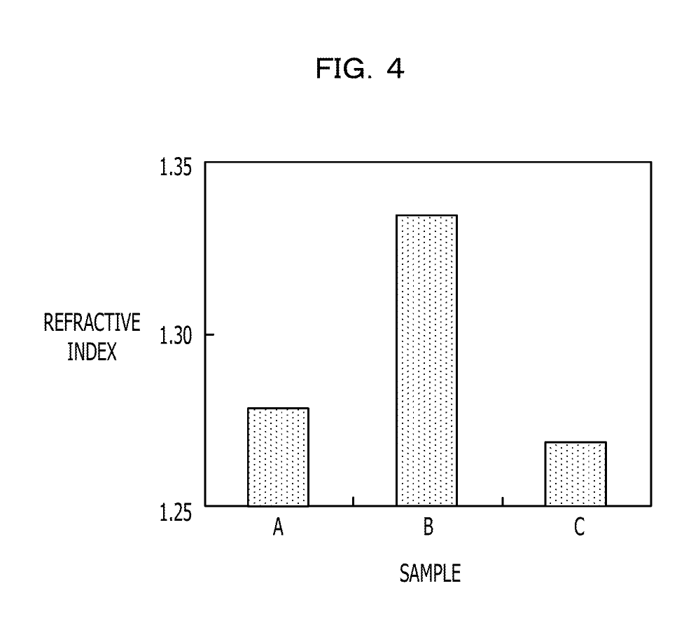

The refractive index of the low dielectric constant film lk of each of the samples A, B and C is measured. FIG. 4 illustrates exemplary refractive indices of low dielectric constant films. The refractive indices illustrated in FIG. 4 may be those of the low dielectric constant films lk of the samples A, B and C. The vertical axis of FIG. 4 represents the refractive index of the low dielectric constant film. As illustrated in FIG. 4, the refractive index of the low dielectric constant film lk of the sample A is 1.275, the refractive index of the low dielectric constant film lk of the sample B is 1.33, and the refractive index of the low dielectric constant film lk of the sample C is 1.26.

The layer having damage by etching may absorb moisture and the refractive index of the low dielectric constant film lk of the sample B may increase. Since the damage is recovered by the UV irradiation and the surface of the low dielectric constant film lk recovers the hydrophobicity, the refractive index of the low dielectric constant lk of the sample C may decrease to 1.26.

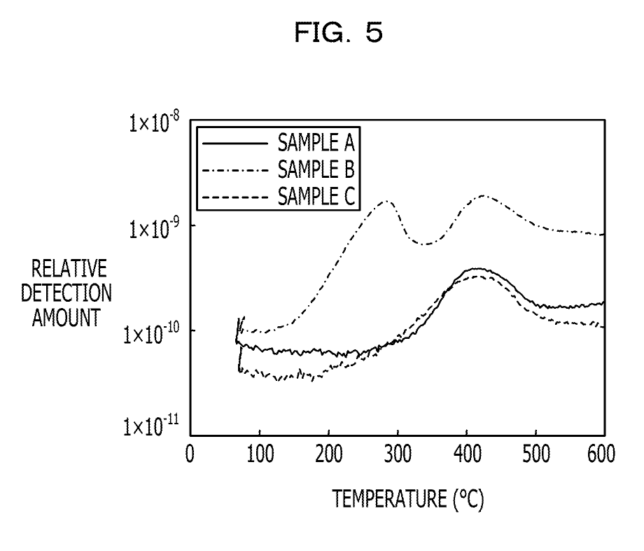

The degassing from the samples A, B and C is analyzed. FIG. 5 illustrates an exemplary degassing analysis. The degassing analysis illustrated in FIG. 5 may be the degassing analysis of each of the samples A, B and C. A thermal desorption spectroscopy (TDS) device is used, the samples A, B, and C are heated by infrared rays in a vacuum, and the emitted gas is measured by a quadrupole mass spectrometer. The horizontal axis of FIG. 5 represents the heating temperature (° C.) of the low resistance silicon substrate ss. The vertical axis represents a relative detection amount of gas with a mass number of 18. As illustrated in FIG. 5, in the measurement of the sample B, the peak of the gas with a mass number of 18 is measured at a heating temperature of about 280° C. and a heating temperature of about 420° C. The peaks may be accompanied with the release of water (H₂O). In the samples A and C, the peak may not be measured at a heating temperature of at least about 280° C. The low dielectric constant film lk of the sample B may absorb a larger amount of moisture than that of the low dielectric constant film 1k of the sample C. In the sample C, the hygroscopicity of the low dielectric constant film lk may decrease due to the UV irradiation.

The damage to the low dielectric constant film may be recovered by the UV irradiation after the etching, and the moisture absorbability of the low dielectric constant film may be removed.

The substrate temperature during the UV irradiation may be 25° C. to 300° C. The UV irradiation may be performed, for example, after forming a low dielectric constant film wiring groove in a single damascene process or after forming a wiring groove and a via hole in a dual damascene process. The UV irradiation may be performed in a state where a lower wiring is exposed from the wiring groove and the via hole. Therefore, when the substrate temperature during the UV irradiation is high, materials of the lower wiring, e.g., Cu, may be spouted. For example, when the substrate temperature is 300° C. or lower, the spouting of the materials of the wiring may be reduced. When the substrate temperature is lower than 25° C., the effects of the UV irradiation may decrease. The substrate temperature during the UV irradiation may be 25° C. to 300° C.

The oxygen gas (O₂ gas) concentration in a gas atmosphere during the UV irradiation may be 50 ppm or lower. When the UV irradiation is performed in an atmosphere in which the oxygen gas concentration exceeds 50 ppm, the surface of the lower wiring may be easily oxidized. The atmosphere gas during the UV irradiation that recovers the damage to the low dielectric constant film may include inactive gas, such as He gas, Ar gas, or N₂ gas, for example. He gas with high thermal conductivity cools the substrate, and thus He gas may be used. The spouting of wiring materials is reduced. When the UV irradiation is performed under an He gas atmosphere, the substrate temperature may be set to 25° C. to 300° C. and the chamber internal pressure power may be set to 500 mTorr to 50 Torr, for example. The atmosphere gas during the UV irradiation may be mixed gas including two or more kinds of He gas, Ar gas and N₂ gas.

The UV irradiation time may be 10 minutes or more, for example. A sample D is prepared by substantially the same or similar process of that of the sample C under the conditions where the UV irradiation time is set to 15 minutes.

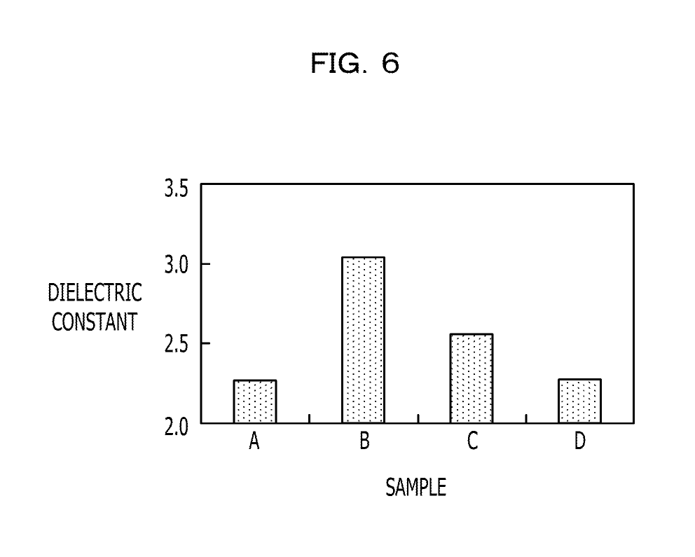

The dielectric constant of the low dielectric constant film lk of the sample D is calculated to be 2.3 by capacity measurement using an LCR meter. The dielectric constant of the low dielectric constant film lk of the sample D is lower than the dielectric constant of the sample C of 2.5 and is substantially the same as the dielectric constant of the sample A of about 2.3. The dielectric constant of the low dielectric constant film lk may be recovered to the state before the etching by the UV irradiation. FIG. 6 illustrates exemplary dielectric constants of the low dielectric constant films. The dielectric constants illustrated in FIG. 6 may be those of the low dielectric constant films lk of the samples A to D.

The conditions of the UV irradiation to the low dielectric constant film lk during the production of the sample C may be set based on the substrate temperature, the atmosphere gas, the irradiation time, and the like.

Samples E, F and G are produced. In the sample E, a low dielectric constant film lk of 100 nm in thickness is formed on a low resistance silicon substrate ss under the same production conditions as those of the sample A. A 50-nm-thick portion of the low dielectric constant film lk is removed by etching under the same production conditions as those of the sample B. The low dielectric constant film lk is subjected to a process in which hexamethyldisilazane (HMDS), which is one kind of a carbon containing chemical species, is made to act (HMDS process). An Au upper electrode ue is formed on the low dielectric constant film lk under the same production conditions as those of the sample A. The UV irradiation may not be performed. The HMDS process is performed at 110° C. for 30 seconds as a vapor process. In the sample F, UV is emitted for 3 minutes and the same process as the production process of the sample C is performed. The HMDS process may not be performed. In the sample G, UV is emitted for 3 minutes between the HMDS process and the formation of the Au upper electrode ue and the same process as the production process of the sample E is performed. The UV irradiation conditions other than the irradiation time may be substantially the same as or similar to the production conditions of the sample A.

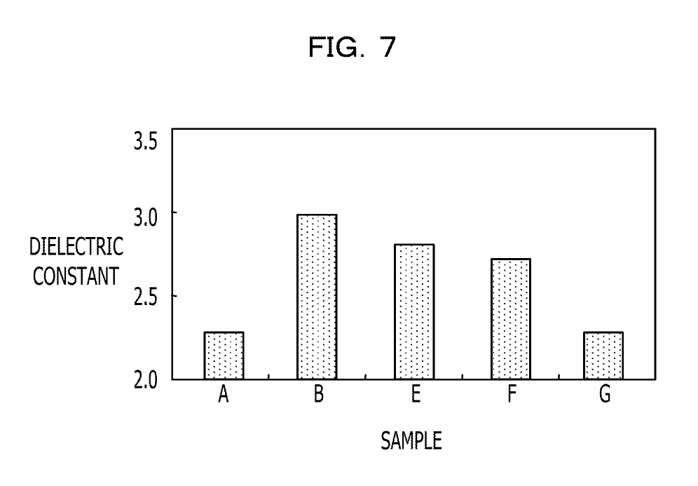

The dielectric constant of the low dielectric constant film lk of each of the sample E, F and G is computed by capacity measurement using an LCR meter. FIG. 7 illustrates an exemplary dielectric constant of a low dielectric constant film. The dielectric constants illustrated in FIG. 7 may be those of the low dielectric constant films lk of the samples A, B, E, F and G. As illustrated in FIG. 7, the dielectric constant of the sample E that has not been irradiated with UV is 2.8 and is lower than the dielectric constant of the sample B. The damage may be recovered by the HMDS process. The dielectric constant of the sample F irradiated with UV for a short time is 2.75. The sample G to which the HMDS process is performed in addition to the production process of the sample F has substantially the same dielectric constant as the dielectric constant of the sample A, i.e., 2.3. When the HMDS process is performed in the case where the UV irradiation time is short, the damage may be recovered and the dielectric constant may be reduced.

When the UV irradiation is performed during oxide reduction of a natural oxide film or the like on the surface of wiring exposed from the wiring groove before the barrier metal film is formed in the wiring groove in the damascene process, the reduction and the UV irradiation may be performed in a short period of time. Since a reduction gas is excited by UV, the reduction efficiency may be greatly improved. When the process from the UV irradiation after forming the wiring groove to the formation of the barrier metal film in the wiring groove is performed in one chamber without releasing the air from the chamber, the function of the barrier metal film may be demonstrated and the reliability of a semiconductor device may increase. When the process from the UV irradiation to the formation of the barrier metal film is performed, for example, in a vacuum, the low dielectric constant film that is recovered from the damages is isolated from the air containing moisture. By isolation from the air, the moisture absorption of the low dielectric constant film decreases and the barrier metal film is formed, and thus the oxidization of the barrier metal film may be reduced.

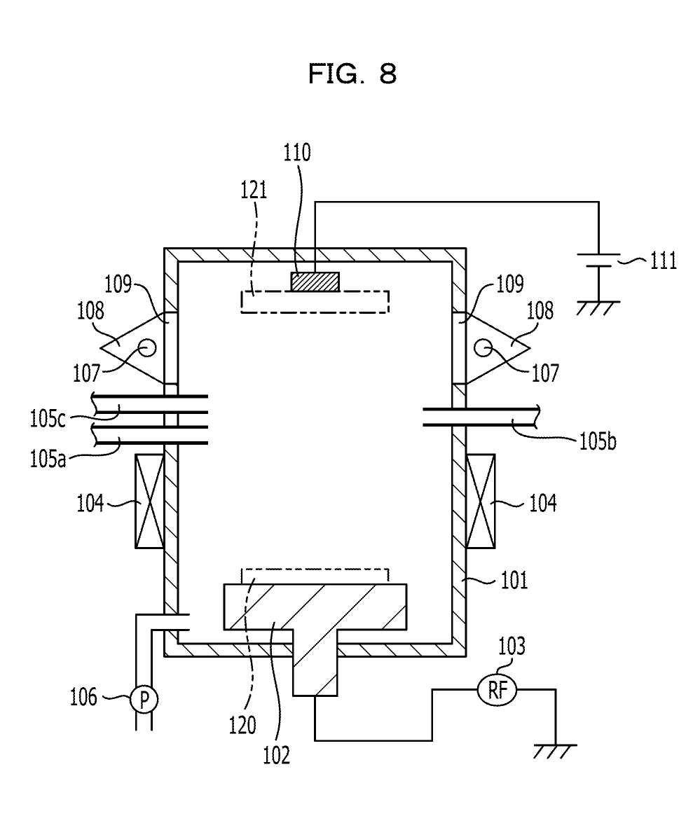

FIG. 8 illustrates an exemplary semiconductor device manufacturing apparatus.

In a semiconductor device manufacturing apparatus illustrated in FIG. 8, a stage 102 is provided at a lower portion of a chamber 101. A substrate 120, on which the barrier metal film is formed, is placed on the stage 102. To the stage 102, an RF signal is applied from an RF source 103. A holder 110 that holds a target corresponding to a raw material of the barrier metal film is provided at an upper portion of the chamber 101. A bias voltage is applied from a bias power supply 111 to the holder 110. Permanent magnets 104 are provided around the stage 102. A reduction-gas introduction line 105a that introduces a reduction gas, such as H₂ gas, into the chamber 101, a carbon-containing-source introduction line 105b that introduces a carbon containing chemical species, such as HMDS, into the chamber 101, and an inactive-gas introduction line 105c that introduces an inactive gas, such as He gas, into the chamber 101 are provided. A pump 106 that reduces the pressure inside the chamber 101 is provided. A quartz window 109 is attached to part of the wall of the chamber 101. A UV valve 107 (ultraviolet ray source) is provided to the outside of the quartz window 109. A light reflector 108 that leads UV from the UV valve 107 to the substrate 120 on the stage 102 through the quartz window 109 is provided around the UV valve 107. The wavelength of the UV emitted from the UV valve 107 may be about 150 nm to about 400 nm, for example.

The film forming device carries out the HMDS process, the UV irradiation, and the reduction process of the substrate 120 in the chamber 101 without releasing the air from the chamber. Two or more kinds of processes among the above-described processes may be substantially contemporaneously performed. The film forming device forms the barrier metal film by a physical vapor deposition (PVD) method.

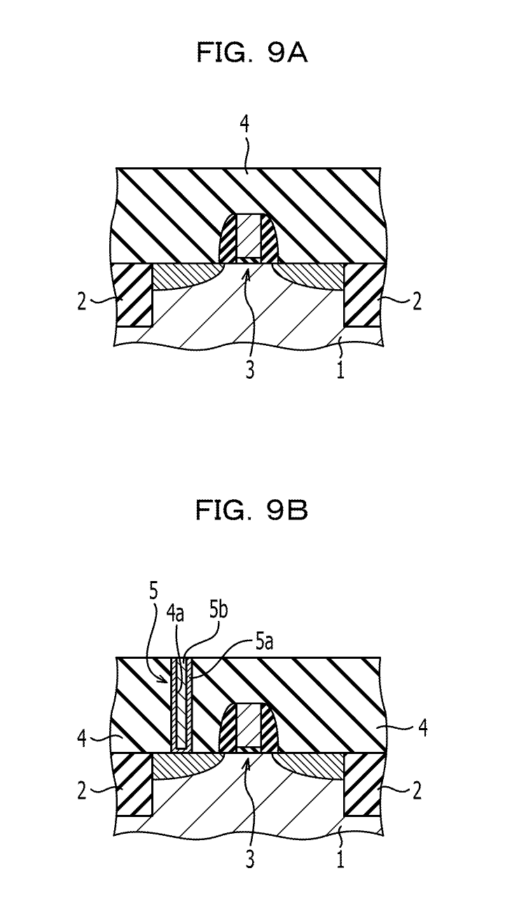

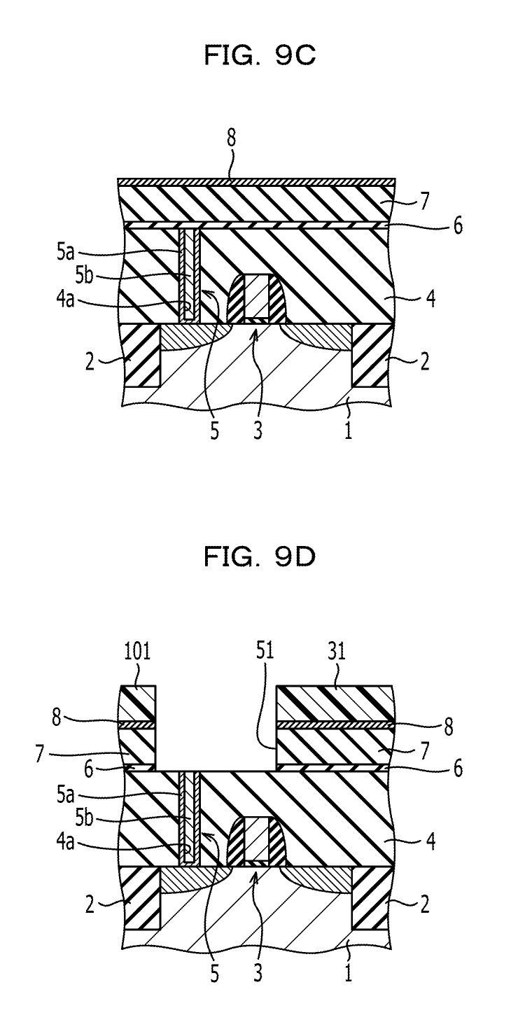

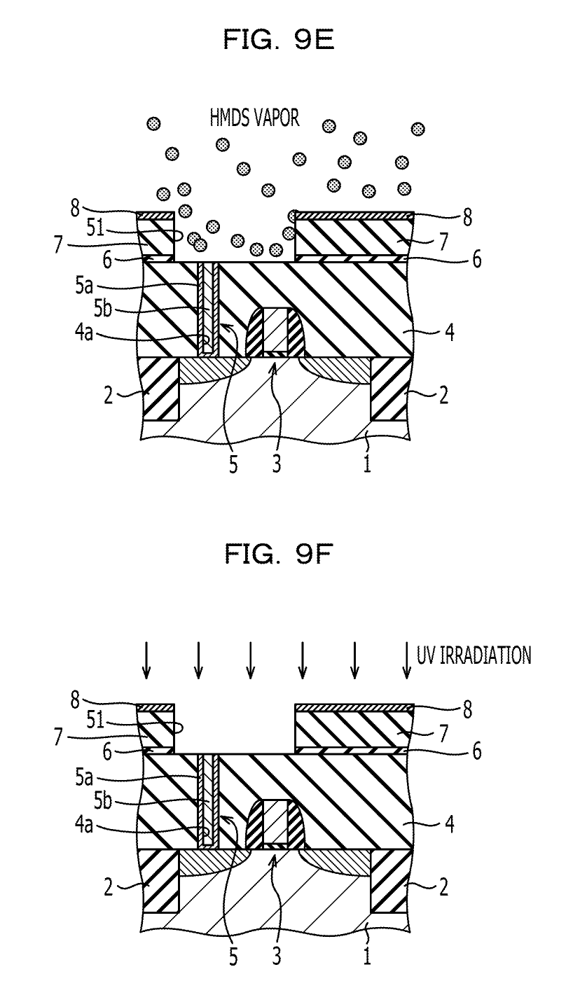

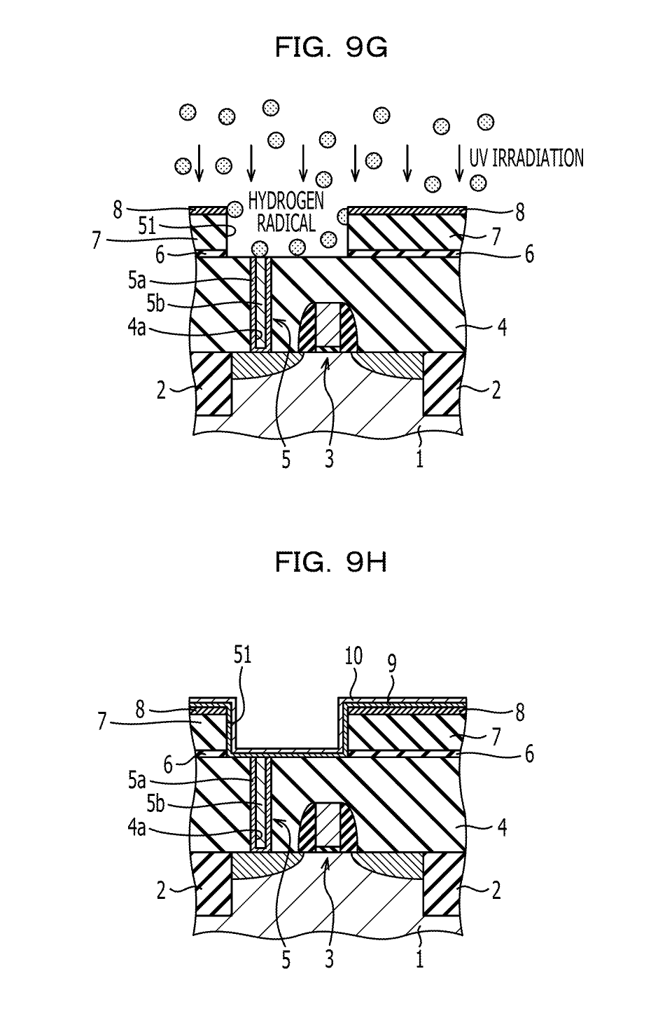

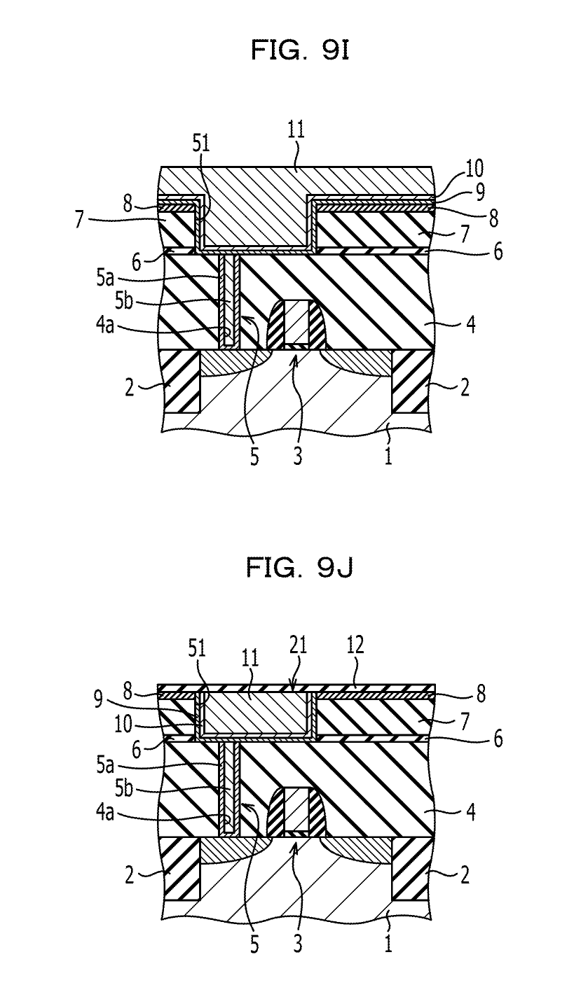

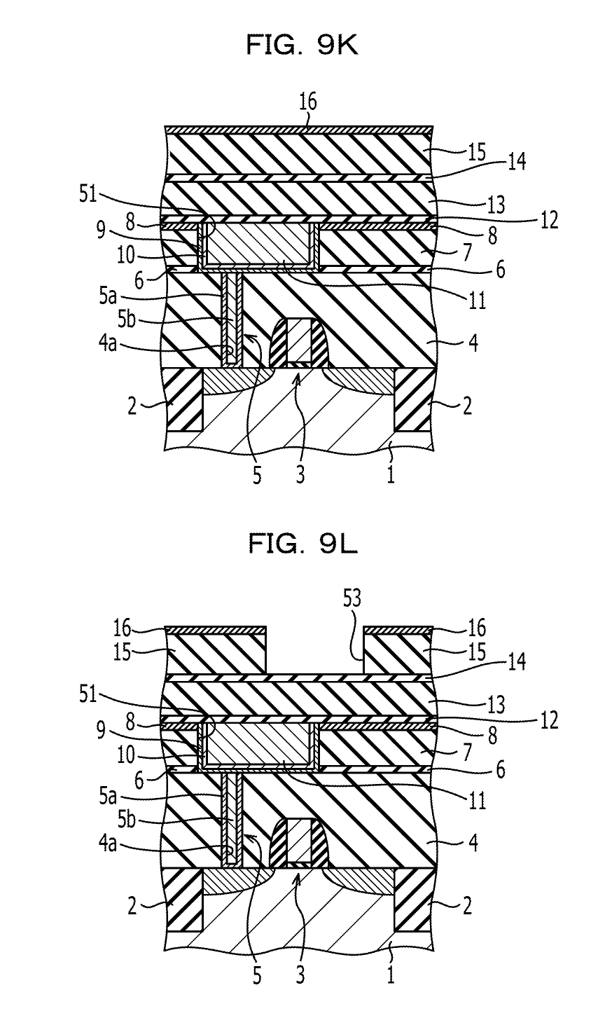

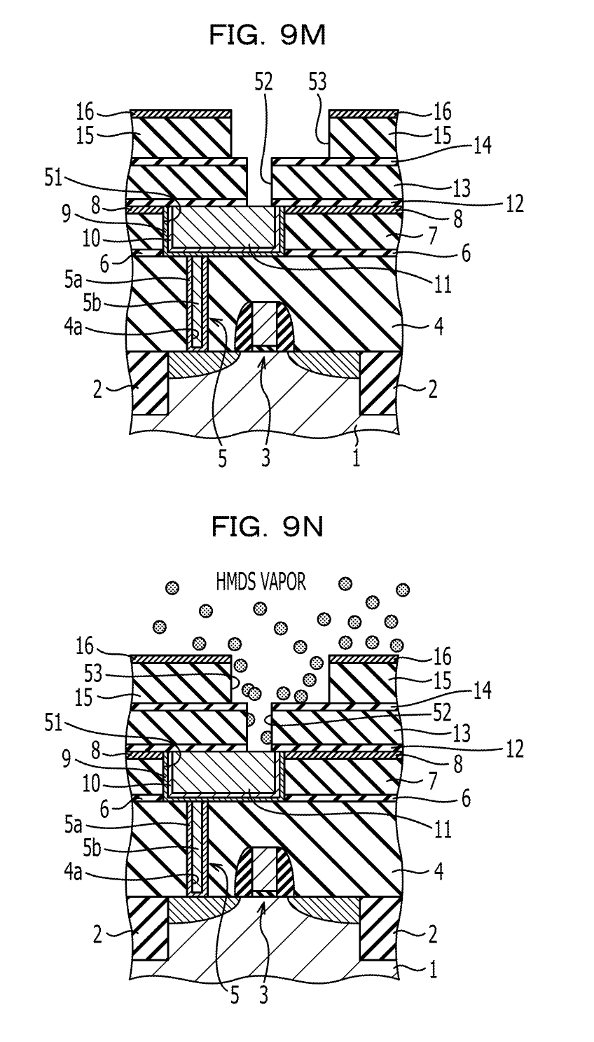

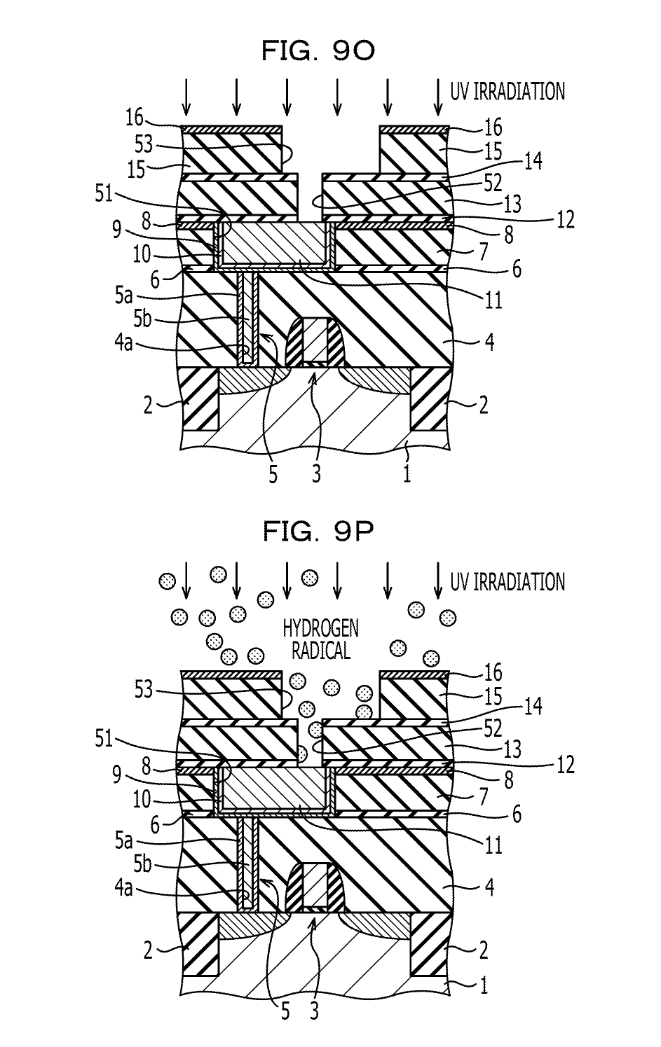

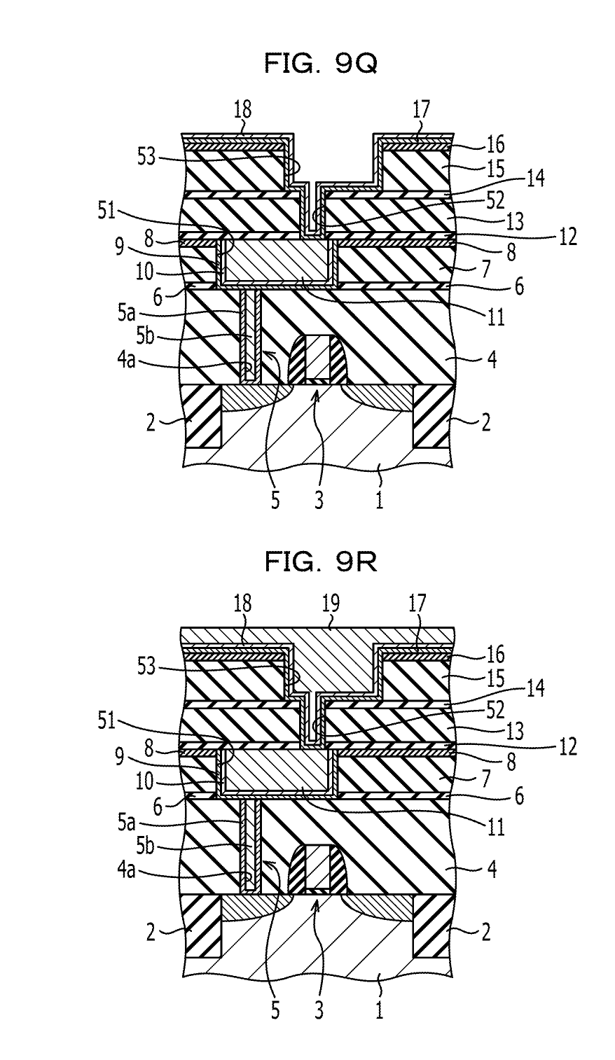

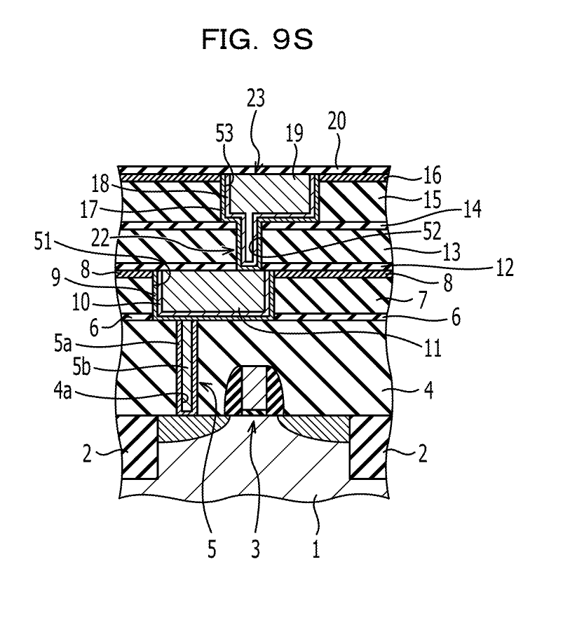

FIGS. 9A to 9S illustrate an exemplary method of manufacturing a semiconductor device.

As illustrated in FIG. 9A, an element separation insulating film 2 is formed on the surface of a semiconductor substrate 1 by, for example, a shallow trench isolation (STI) method. A MOS transistor 3 is formed in an active region defined by the element separation insulating film 2. The MOS transistor 3 includes a source diffusion layer, a drain diffusion layer, a gate insulating film, a gate electrode, and the like. For example, the gate length may be about 65 nm and the thickness of the gate insulating film may be 2 nm. An interlayer insulating film 4 covering the MOS transistor 3 is formed by, for example, a chemical vapor deposition (CVD) method. For example, the interlayer insulating film 4 may include a phosphosilicate glass PSG and the thickness of the interlayer insulating film 4 may be 1.5 μm. For high-speed operation of the MOS transistor 3, a low resistance metal silicide layer such as a Co silicide layer or a Ni silicide layer may be formed on the surface of the source diffusion layer, the drain diffusion layer, and the gate electrode before forming the interlayer insulating film 4.

As illustrated in FIG. 9B, a contact hole 4a reaching the source diffusion layer and the drain diffusion layer is formed by etching in the interlayer insulating film 4. A barrier metal film 5a is formed so as to cover the inner wall surface of the contact hole 4a, a conductive film 5b is formed on the barrier metal film 5a, and the conductive film 5b and the barrier metal film 5a are removed until the surface of the interlayer insulating film 4 is exposed by a chemical mechanical polishing (CMP) method. A contact plug 5 including the barrier metal film 5a and the conductive film 5b is formed in the contact hole 4a. For example, the conductive film 5b may include a W film and the barrier metal film 5a may include a TiN film.

As illustrated in FIG. 9C, an etching stopper film 6 is formed on the interlayer insulating film 4 and the contact plug 5. The etching stopper film 6 may include a 50-nm-thick SiC film, for example. In the formation of the SiC film, tetramethylsilane gas may be supplied into the chamber at a flow rate of 1,000 sccm, CO₂ gas may be supplied into the chamber at a flow rate of 2,500 sccm, the high frequency (HF) power may be set to 500 W, the low frequency (LF) power may be set to 400 W, and the pressure in the chamber may be set to 2.3 Torr, for example. The etching stopper film 6 may include a SiO₂ film, a SiOC film, or a SiN film. A low dielectric constant film 7 as an interlayer insulating film is formed on the etching stopper film 6 by, for example, a spin-on process. Materials of the low dielectric constant film 7 may include, for example, an MSQ/HSQ mixed hybrid type porous silica (e.g., NCS® manufactured by Catalysts and Chemicals Industries CO., Ltd) which is a low dielectric constant material. The thickness of the low dielectric constant film 7 may be 250 nm. Baking process is performed at 250° C. for 1 minute, the temperature of the semiconductor substrate 1 is set to 400° C. in a nitrogen atmosphere, and heat process for 30 minutes is performed. A sacrificial layer 8 is formed on the low dielectric constant film 7. The sacrificial layer 8 may include a 30-nm-thick SiO₂ film, for example. The sacrificial layer 8 may include a SiOC film, a SiC film, or a SiN film.

As illustrated in FIG. 9D, a resist pattern 31 for opening a region, where a wiring groove is to be formed, is formed on the sacrificial layer 8. The sacrificial layer 8, the low dielectric constant film 7, and the etching stopper film 6 are etched using the resist pattern 31 as a mask, so that a wiring groove 51 (opening portion) is formed. For example, RIE using CF₄ gas as etching gas may be performed, the RF power may be set to 250 W, and the pressure in the chamber may be set to 20 mTorr.

As illustrated in FIG. 9E, the resist pattern 31 is removed by asking. For example, the semiconductor substrate 1 is conveyed into the chamber 101 of the film forming device illustrated in FIG. 8, and the HMDS process is performed in the chamber 101. In the HMDS process, HMDS gas is introduced into the chamber 101 from the carbon-containing-source introduction line 105b, the temperature of the semiconductor substrate 1 is set to 110° C., and the wiring groove 51 is exposed to a vaporized HMDS atmosphere for 30 seconds. By the HMDS process, damage to the bottom surface or the side surface of the wiring groove 51 may be recovered.

The introduction of the HMDS gas is stopped, and He gas is introduced into the chamber 101 from the inactive-gas introduction line 105c. The pressure in the chamber 101 is set to 10 Torr with a pump 106 and the oxygen gas concentration in the chamber 101 is set to 50 ppm or lower. A UV valve 107 emits light, so that the wiring groove 51 is irradiated with UV in the chamber 101 as illustrated in FIG. 9F. For example, the intensity of the UV may be 350 mW/cm² and the irradiation period of time may be 10 minutes. By the UV irradiation, damage to the bottom surface or the side surface of the wiring groove 51 may be recovered.

The introduction of the He gas is stopped, and H₂ gas is introduced into the chamber 101 from the reduction-gas introduction line 105a while continuing the UV irradiation. The pressure in the chamber 101 may be 2 Torr to 50 Torr. As illustrated in FIG. 9G, the H₂ gas is excited by the UV and a hydrogen radical is generated. Therefore, a natural oxide film on the surface of the contact plug 5 is reduced with high efficiency. Since the UV irradiation is continued, the damage present on the bottom surface and the side surface of the wiring groove 51 may be recovered.

In a state where the introduction of the H₂ gas and the UV irradiation are stopped and the atmosphere in the chamber 101 is isolated from the air, a barrier metal film 9 is formed by a sputtering method on the bottom surface and the side surface of the wiring groove 51 and on the sacrificial layer 8 as illustrated in FIG. 9H. The barrier metal film 9, e.g., a Cu-diffusion preventive film, may include a 30-nm-thick Ta film, for example. Materials of the barrier metal film 9 may be attached to the holder 110 as a target 121 before the HMDS process. In a state where the atmosphere in the chamber 101 is isolated from the air, the target 121 is exchanged and a seed film 10 is formed on the barrier metal film 9 by a sputtering method. The seed film 10 may include a 30-nm-thick Cu film, for example.

The semiconductor substrate 1 is taken out from the chamber 101. As illustrated in FIG. 9I, a conductive film 11 is formed on the seed film 10 by a plating method. The conductive film 11 may include a 500-nm-thick Cu film, for example.

The conductive film 11, the seed film 10, and the barrier metal film 9 are removed by a CMP method until the surface of the sacrificial layer 8 is exposed. Therefore, as illustrated in FIG. 9J, a wiring 21 including the conductive film 11, the seed film 10, and the barrier metal film 9 is formed in the wiring groove 51. A cap film 12, e.g., a Cu-diffusion preventive cap film, is formed on the sacrificial layer 8 and the wiring 21. The cap film 12 may include a 50-nm-thick SiO₂ film, for example.

As illustrated in FIG. 9K, an interlayer insulating film, e.g., the low dielectric constant film 13, the etching stopper film 14, an interlayer insulating film, e.g., the low dielectric constant film 15, and the sacrificial layer 16 are formed in this order on the cap film 12. The low dielectric constant film 13 includes a 250-nm-thick MSQ/HSQ mixed hybrid type porous silica film, for example. The etching stopper film 14 includes a 30-nm-thick SiC film, for example. The etching stopper film 14 may include a SiO₂ film, a SiOC film, or a SiN film. The low dielectric constant film 15 may include a 170-nm-thick MSQ/HSQ mixed hybrid type porous silica film, for example. The sacrificial layer 16 may include an about 50-nm-thick SiO₂ film, for example. The sacrificial layer 16 may include a SiOC film, a SiC film, a SiN film, and the like.

A resist pattern for opening a region, where a wiring groove is to be formed, is formed on the sacrificial layer 16. The sacrificial layer 16 and the low dielectric constant film 15 are etched using the resist pattern as a mask, so that a wiring groove 53, e.g., an opening portion, is formed as illustrated in FIG. 9L.

A resist pattern for opening a region, where a via hole is to be formed, is formed on the sacrificial layer 16 and the etching stopper film 14. The etching stopper film 14, the low dielectric constant film 13, and the cap film 12 are etched using the resist pattern as a mask, so that a via hole 52, e.g., an opening portion, is formed as illustrated in FIG. 9M.

For example, the semiconductor substrate 1 is conveyed into the chamber 101 of the film forming device illustrated in FIG. 8, and the HMDS process is performed in the chamber 101 as illustrated in FIG. 9N. In the HMDS process, HMDS gas is introduced into the chamber 101 from the carbon-containing-source introduction line 105b, the temperature of the semiconductor substrate 1 is set to 110° C., and the wiring groove 53 and the via hole 52 are exposed to a vaporized HMDS atmosphere for 30 seconds. By the HMDS process, damage to the bottom surface or the side surface of the wiring groove 53 and the via hole 52 may be recovered.

The introduction of the HMDS gas is stopped, and He gas is introduced into the chamber 101 from the inactive-gas introduction line 105c. The pressure in the chamber 101 is set to 10 Torr with the pump 106, and the oxygen gas concentration in the chamber 101 is set to 50 ppm or lower. The UV valve 107 emits light, so that the wiring groove 53 and the via hole 52 are irradiated with UV in the chamber 101 as illustrated in FIG. 9O. For example, the intensity of the UV may be 350 mW/cm² and the irradiation time may be 10 minutes. The damage to the bottom surface or the side surface of the wiring groove 53 and the via hole 52 may further be recovered by the UV irradiation.

The introduction of the He gas is stopped, and H₂ gas is introduced into the chamber 101 from the reduction-gas introduction line 105a while continuing the UV irradiation. The pressure in the chamber 101 may be 2 Torr to 50 Torr. As illustrated in FIG. 9P, the H₂ gas is excited by UV and a hydrogen radical is generated. Therefore, a natural oxide film on the surface of the wiring 21 is reduced with high efficiency. Since the UV irradiation is continued, the damage to the bottom surface or the side surface of the wiring groove 53 and the via hole 52 may be recovered.

The introduction of the H₂ gas and the UV irradiation are stopped, and in a state where the atmosphere in the chamber 101 is isolated from the air, a barrier metal film 17 is formed by a sputtering method on the bottom surface and the side surface of the wiring groove 53 and the via hole 52 and on the sacrificial layer 16 as illustrated in FIG. 9Q. The barrier metal film 17, e.g., a Cu-diffusion preventive film, includes a 30-nm-thick Ta film, for example. Materials of the barrier metal film 17 may be attached to the holder 110 as the target 121 before the HMDS process. A seed film 18 is formed on the barrier metal film 17 by a sputtering method. The seed film 18 may include a 30-nm-thick Cu film, for example.

The semiconductor substrate 1 is taken out from the chamber 101 and a conductive film 19 is formed on the seed film 18 by a plating method as illustrated in FIG. 9R. The conductive film 19 may include a 500-nm-thick Cu film, for example.

The conductive film 19, the seed film 18, and the barrier metal film 17 are removed by a CMP method until the surface of the sacrificial layer 16 is exposed. Therefore, as illustrated in FIG. 9S, a wiring 23 including the conductive film 19, the seed film 18, and the barrier metal film 17 is formed in the wiring groove 53 and a via plug 22 including the conductive film 19, the seed film 18, and the barrier metal film 17 is formed in the via hole 52. A cap film 20, e.g., a Cu-diffusion preventive cap film, is formed on the sacrificial layer 16 and the wiring 52. The cap film 20 may include a 50-nm-thick SiO₂ film, for example.

The same process is repeated to form a multilayer wiring and form a passivation film, a pad, and the like, whereby a semiconductor device is formed.

The low dielectric constant films 7, 13, and 15 are etched and the HMDS process and the UV irradiation are performed. Therefore, damage to the low dielectric constant films 7, 13, and 15 is recovered. The dielectric constant of each of the low dielectric constant films 7, 13, and 15 may not increase and the leakage current thereof may decrease. When the oxide on the surface of each of the contact plug 5 and the wiring 21 is reduced, reduction gas may be excited and the efficiency of the reduction process may increase because the UV irradiation is continuously performed. At least the processes from the UV irradiation to the wiring groove 51 to the formation of the barrier metal film 9 are performed under an atmosphere in which the oxygen gas concentration is 50 ppm or lower and at least the processes from the UV irradiation to the wiring groove 53 and the via hole 52 to the formation of the barrier metal film 17 are performed under an atmosphere in which the oxygen gas concentration is 50 ppm or lower. Therefore, the barrier metal films 9 and 17 are formed in a state where the low dielectric constant films 7, 13 and 15 do not absorb moisture.

The HMDS process may be omitted. Since the UV irradiation is performed in a reduction gas atmosphere, the UV irradiation in an inactive gas atmosphere may be omitted. When the UV irradiation in a reduction gas atmosphere is performed, HMDS may be introduced into the chamber. For example, the UV irradiation and the HMDS process may be substantially contemporaneously performed in a reduction gas atmosphere. The UV irradiation may be performed while the HMDS process is performed, before the UV irradiation in a reduction gas atmosphere.

The low dielectric constant film may include an MSQ/HSQ mixed hybrid type porous silica, a polyarylene film, a polyaryl ether film, a hydrogen silsesquioxane film, a methyl silsesquioxane film, or a silicon oxycarbide film, for example. ALCAP-S (porous silica manufactured by Asahi Chemical Co., Ltd.), Silk (polyaryl ether manufactured by Dow Chemical Co.), FLARE (polyaryl ether manufactured by Allied Signal, Inc.), and the like may be used. A laminate including two or more kinds of the above-mentioned materials may be formed. The UV irradiation, the reduction process, or the like may be performed on insulating films other than the low dielectric constant films, such as a SiO₂ film.

For the carbon containing chemical species, a chemical liquid or the like containing hexamethyldisilane (HMDS) or a methyl group may be used. The chemical liquid containing a methyl group may include tetramethyldisilazane, divinyltetramethyldisilazane, cyclic dimethylsilazane, or heptamethyldisilazane, for example. The chemical liquid may adhere to the surface of the low dielectric constant film in vapor process or the low dielectric constant film may be immersed in the chemical liquid formed into a solution.

The carbon containing chemical species may be carbon containing gas. The low dielectric constant film may be exposed to gas, such as ethylene gas and/or acetylene gas. For example, the flow rate of the ethylene gas is set to 500 sccm, the pressure in a chamber is set to 3 Torr, the low dielectric constant film is held in the chamber for 1 minute, and the UV irradiation may be performed. The carbon in gas may be activated by the UV irradiation, and the activated carbon may recover damage to the low dielectric constant film. Ethylene gas or the like may be added to the atmosphere during the UV irradiation. The carbon containing gas may include hydrocarbon gas, such as ethylene gas or acetylene gas or organosilane gas, such as tetramethylcyclotetrasiloxane, tricyclotetrasiloxane, dimethylphenylsilane (DMPS), or trimethylsilylacetylene (TMSA). Two or more kinds of the gas may be combined.

The UV source may include a low-pressure mercury lamp or an excimer laser. The wavelength of the UV emitted from an excimer laser is short e.g., 172 nm, and thus the damage may be recovered by short-time irradiation. Two or more kinds of UV sources may be combined. For example, the UV irradiation may be performed by the excimer laser, and then the UV irradiation with a high-pressure mercury lamp may be performed.

The barrier metal film may contain Ta, TaN, Ti, TiN, W, WN, Zr, or ZrN. A laminate containing two or more kinds of materials may be formed. Raw materials of wiring may include Cu, Cu alloy, W, W alloy, or the like.

Example embodiments of the present invention have now been described in accordance with the above advantages. It will be appreciated that these examples are merely illustrative of the invention. Many variations and modifications will be apparent to those skilled in the art.

1. A method of manufacturing a semiconductor device, comprising:
forming a first conductive film on a substrate;
forming an insulating film to cover the conductive film;
etching the insulating film to form an opening portion to expose at least a portion of the first conductive film in the insulating film;
irradiating the opening portion with ultraviolet rays in a reduction gas atmosphere;
forming a barrier metal film in the opening portion; and
forming a second conductive film on the barrier metal film.

2. The method of manufacturing a semiconductor device according to claim 1, further comprising:
irradiating the opening portion with the ultraviolet rays without releasing an atmosphere from the chamber; and
forming the barrier metal film.

3. The method of manufacturing a semiconductor device according to claim 1, further comprising:
irradiating the opening portion with the ultraviolet rays in an atmosphere in which the oxygen gas concentration is 50 ppm or lower; and
forming the barrier metal film.

4. The method of manufacturing a semiconductor device according to claim 1, wherein
the insulating film includes a low dielectric constant film.

5. The method of manufacturing a semiconductor device according to claim 1, wherein
the insulating film includes carbon.

6. The method of manufacturing a semiconductor device according to claim 1, further comprising,
irradiating the opening portion with ultraviolet rays in an inactive gas atmosphere after forming the opening portion.

7. The method of manufacturing a semiconductor device according to claim 1, further comprising,
supplying a carbon including chemical species to the opening portion after forming the opening portion.

8. The method of manufacturing a semiconductor device according to claim 6, further comprising,
supplying a carbon including chemical species to the opening portion when irradiating the opening portion with ultraviolet rays in the inactive gas atmosphere.

9. The method of manufacturing a semiconductor device according to claim 1, further comprising:
supplying a carbon including chemical species to the opening portion when irradiating the opening portion with ultraviolet rays in the reduction gas atmosphere.

10. The method of manufacturing a semiconductor device according to claim 7, wherein
the carbon containing chemical species includes a methyl group.

11. The method of manufacturing a semiconductor device according to claim 7, wherein
the carbon containing chemical species includes at least one selected from the group consisting of hexamethyldisilazane, tetramethyldisilazane, divinyltetramethyldisilazane, cyclic dimethylsilazane, and heptamethyldisilazane.

12. The method of manufacturing a semiconductor device according to claim 7, wherein
the carbon containing chemical species includes at least one selected from the group consisting of hydrocarbon gas and organosilane gas.

13. The method of manufacturing a semiconductor device according to claim 12, wherein
the hydrocarbon gas includes at least one selected from the group consisting of ethylene gas and acetylene gas.

14. The method of manufacturing a semiconductor device according to claim 12, wherein
the organosilane gas includes at least one selected from the group consisting of tetramethylcyclotetrasiloxane gas, tricyclotetrasiloxane gas, DMPS gas, and TMSA gas.

15. The method of manufacturing a semiconductor device according to claim 1, wherein
the wavelength of the ultraviolet rays is 150 nm to 400 nm.

16. The method of manufacturing a semiconductor device according to claim 1, wherein
the reduction gas atmosphere includes hydrogen.

17. The method of manufacturing a semiconductor device according to claim 1, wherein
the temperature of the substrate is set to 25° C. to 300° C. during the irradiation of the ultraviolet rays.

18. A semiconductor device manufacturing apparatus, comprising:
a stage provided in a chamber, the stage being capable of supporting a wafer;
a pressure reducing device to reduce pressure inside the chamber;
a reduction-gas supply device to supply reduction gas into the chamber; and
a ultraviolet-ray irradiation device to irradiate the stage with ultraviolet rays.

19. The semiconductor device manufacturing apparatus according to claim 18, further comprising,
a carbon-containing-chemical-species supply device to supply a carbon containing chemical species into the chamber.

20. The semiconductor device manufacturing apparatus according to claim 19, wherein
the carbon containing chemical species includes at least one selected from the group consisting of hexamethyldisilane, tetramethyldisilazane, divinyltetramethyldisilazane, cyclic dimethylsilazane, and heptamethyldisilazane.
